(19) United States
(12) Patent Application Publication
(10) Pub. No.: US 2024/0282662 A1
(43) Pub. Date: Aug. 22, 2024

(54) POWER MODULE

(71) Applicant: UT-Battelle, LLC, Oak Ridge, TN (US)

(72) Inventors: Md Shajjad Chowdhury, Knoxville, TN (US); Emre Gurpinar, Knoxville, TN (US); Burak Ozpineci, Knoxville, TN (US)

(21) Appl. No.: 18/374,410

(22) Filed: Sep. 28, 2023

Related U.S. Application Data
(60) Provisional application No. 63/447,052, filed on Feb. 21, 2023.

(51) Int. Cl. H01L 23/373; H01L 23/00; H01L 23/367; H01L 25/07

(52) U.S. Cl. CPC H01L 23/3735; H01L 23/3672; H01L 24/32; H01L 24/33; H01L 25/072; H01L 2224/32265; H01L 2224/33505; H01L 2924/1517; H01L 2924/15747

(57) ABSTRACT

A multilayer substrate for a power module is provided. The multilayer substrate may include a copper tile soldered between an integrated circuit component and a direct bonded copper assembly in order to facilitate heat dissipation from the integrated circuit component.

### STATEMENT REGARDING FEDERALLY SPONSORED RESEARCH AND DEVELOPMENT

This invention was made with government support under Contract No. DE-AC05-00OR22725 awarded by the U.S. Department of Energy. The government has certain rights in the invention.

### FIELD OF INVENTION

The present disclosure relates to the field of power module packaging, and more particularly to packaging for a wide-band gap (WBG) power device-based power module.

### BACKGROUND

A conventional power module may be constructed by attaching semiconductor dies to a substrate. Such a conventional power module may use a direct bonded copper (DBC) substrate, which has gained popularity, particularly for high-power applications, due to its simplicity, low cost, and maturity. The conventional DBC substrate insulates the live terminals from coolant while efficiently transferring the heat from semiconductor dies. Moreover, the DBC substrate may include electrical terminations and operate as a housing for the semiconductor die. Such a conventional DBC substrate is shown in FIG. 1.

The conventional multilayer structure with the DBC substrate and the semiconductor die utilizes a small area for active heat transfer. Thus, it is not considered to be ideal for smaller wide bandgap, e.g., SiC and GaN, semiconductor devices. In conventional DCB structures, aluminum oxide (Al₂O₃), aluminum nitride (AlN), or silicon nitride (Si₃N₄) is used as an insulator in between two thin copper layers. Due to the high conductivity of the insulator and the low thickness of the coppers, heat cannot spread and comes down vertically. Due to this phenomenon, a small part of the DBC substrate generally transfers the heat from the semiconductor device to the cold plate.

Several conventional approaches have been implemented in an effort to improve the heat extraction capability of a DCB structure. One conventional technique is to sandwich the semiconductor device in between two DBC substrates, called double-sided cooling. This technique can improve heat extraction but has manufacturing yield/repeatability issues due to a complex manufacturing process. Another conventional technique uses an insulated metal substrate (IMS) based power module, where a thin, low thermal conductive, e.g., lower than DBC, insulating material is used with a thick top metal for better heat spreading. These types of substrates utilize most of the area for active heat transfer but show poor performance for restricted space applications as the area of the substrate needs to be large enough to compensate for the low conductive insulating material. A graphene-based IMS has been conventionally considered, where the substrate may provide better performance than the DBC and conventional IMS. However, the latter system still utilizes low conductive insulating materials.

### SUMMARY

In general, one innovative aspect of the subject matter described herein can be a package including a substrate with a ceramic layer, a first Cu layer disposed on one side of the ceramic layer, and a second Cu layer disposed on the opposing side of the ceramic layer. The second Cu layer may be thermally coupled to a heat sink. The package may include a Cu tile having a predetermined thickness, a first side, and a second side opposing the first side, where the first side of the Cu tile may be thermally coupled to an integrated circuit (IC) chip. The package may include a thermally conducting layer sandwiched between the first Cu layer of the substrate and the second side of the Cu tile.

The foregoing and other embodiments can each optionally include one or more of the following features, alone or in combination. In particular, one embodiment includes all of the following features in combination.

In some embodiments, the thermally conducting layer may include solder.

In some embodiments, the predetermined thickness of the Cu tile may be in a range of 0.5 to 2.5 mm.

In some embodiments, the predetermined thickness of the Cu tile is about 1.5 mm.

In some embodiments, the first and second Cu layers of the substrate may have a thickness of about 0.3 mm.

In some embodiments, the ceramic layer of the substrate may include one of Al₂O₃, AlN, or silicon nitride Si₃N₄.

In some embodiments, a power module may incorporate a package according to one embodiment described herein. The power module may include an IC chip, a second thermally conducting layer sandwiched between the first side of the Cu tile and the IC chip, and a heat sink having a thermal interface with the second Cu layer of the substrate.

In some embodiments, the second thermally conducting layer may include solder.

In some embodiments, a power module may include a semiconductor device, wherein the IC chip includes GaN or SiC-based power-electronic switches.

In general, one innovative aspect of the subject matter described herein can be a multilayer substrate for an integrated circuit (IC) component. The multilayer substrate may include a dielectric layer, first and second copper layers disposed on opposing sides of the dielectric layer, and a copper tile including a first side and a second side that opposes the first side. The second side of the copper-based tile may be coupled to the first copper layer, and the first side of the copper tile may be configured to thermally couple to an integrated circuit (IC) component.

In some embodiments, the multilayer substrate may include a thermally conducting layer sandwiched between the first copper layer and the second side of the copper tile.

In some embodiments, the thermally conducting layer may include solder.

In some embodiments, the dielectric layer may be a ceramic layer.

In some embodiments, the ceramic layer may include one of Al₂O₃, AlN, or silicon nitride Si₃N₄.

In some embodiments, the copper tile may have a predetermined thickness.

In some embodiments, the second copper layer may be thermally coupled to a heat sink.

In some embodiments, a power module can comprise a multilayer substrate according to one embodiment described herein. The power module may include an integrated circuit component, a second thermally conducting layer disposed between the first side of the copper tile and the integrated circuit component, and a heat sink operable to thermally interface with the second copper layer.

In some embodiments, the second thermally conducting layer may include solder.

In some embodiments, the integrated circuit component may include a GaN-based or SiC-based power electronic switch.

In some embodiments, the copper tile may include copper and one or more additional conductive metals.

Before the embodiments of the invention are explained in detail, it is to be understood that the invention is not limited to the details of operation or to the details of construction and the arrangement of the components set forth in the following description or illustrated in the drawings. The invention may be implemented in various other embodiments and of being practiced or being carried out in alternative ways not expressly disclosed herein. Also, it is to be understood that the phraseology and terminology used herein are for the purpose of description and should not be regarded as limiting. The use of “including” and “comprising” and variations thereof is meant to encompass the items listed thereafter and equivalents thereof as well as additional items and equivalents thereof. Further, enumeration may be used in the description of various embodiments. Unless otherwise expressly stated, the use of enumeration should not be construed as limiting the invention to any specific order or number of components. Nor should the use of enumeration be construed as excluding from the scope of the invention any additional steps or components that might be combined with or into the enumerated steps or components. Any reference to claim elements as “at least one of X, Y and Z” is meant to include any one of X, Y or Z individually, and any combination of X, Y and Z, for example, X, Y, Z; X, Y; X, Z; and Y, Z.

### BRIEF DESCRIPTION OF THE DRAWINGS

FIG. 1 shows a conventional power module.

FIG. 2 shows a sectional view of a power module according to one embodiment of the Present disclosure.

FIG. 3 shows a top view of a power module in FIG. 2.

FIG. 4 shows a plot comparison of a multilayer substrate according to one embodiment relative to several conventional substrates.

FIG. 5 shows a plot comparison of various copper tiles according to one embodiment of the present disclosure.

FIG. 6 shows switching circuitry for a power module according to one embodiment of the present disclosure.

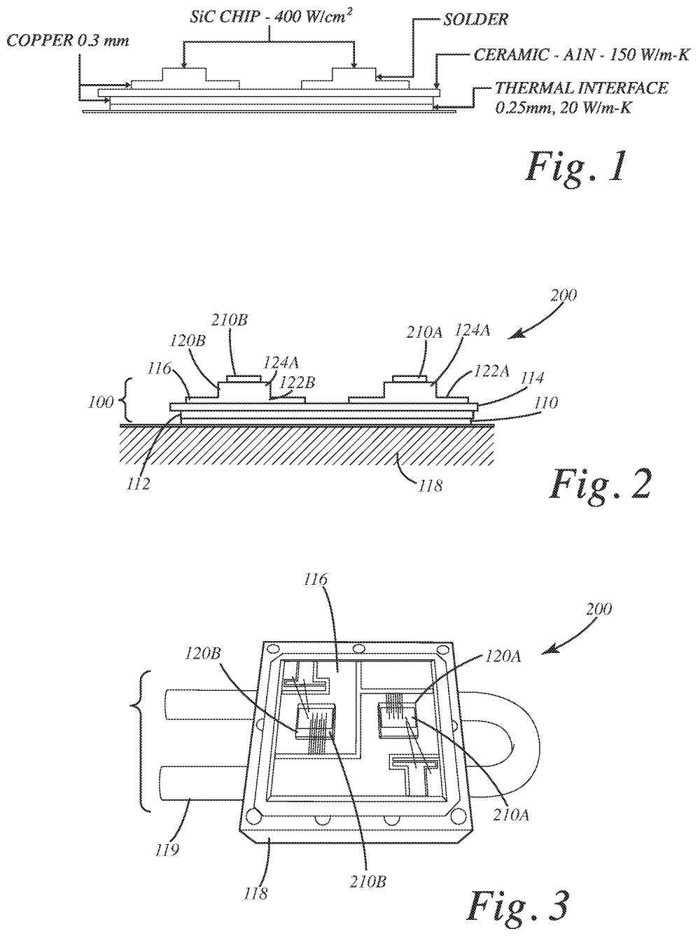

### DETAILED DESCRIPTION

A multilayer substrate for a power module is provided. The multilayer substrate may include a copper tile soldered between an integrated circuit component and a direct bonded copper assembly or substrate in order to facilitate better heat dissipation from the integrated circuit component.

The power module may be constructed by attaching semiconductor dies or integrated circuit (IC) chips to a substrate. The power module may utilize a multilayer substrate that is based on a direct bonded copper (DBC) substrate, which can be used for high-power applications, due to its simplicity, low cost, and maturity. The multilayer substrate may insulate live terminals of the power module from coolant (potentially thermally coupled to a heat sink of the power module via a coolant system 119) while efficiently transferring the heat from semiconductor dies. Moreover, the multilayer substrate may include electrical terminations and acts as a housing for the semiconductor die. As discussed herein, several conventional power modules utilize DBC substrates—however, these conventional DBC substrates can suffer from poor heat dissipation relative to the IC chip.

A multilayer substrate according to one embodiment may be based on a DBC substrate, such as DBCwCu, where 10×10×1.5 mm copper tiles (potentially in the form of bars or blocks) may be soldered between the DBC and the semiconductor device (e.g., an IC chip or semiconductor die) to improve heat spreading. This configuration may provide superior performance over conventional DBC substrates, and also may provide better performance over double-sided DBC based substrates.

In one embodiment, a DBC based substrate is provided in which a 10×10×1.5 mm copper tile (also described as a core) is sandwiched between the semiconductor device and DBC substrate to improve heat extraction capability. A multilayer substrate (e.g., multilayer substrate 100) according to one embodiment may provide a 10% or greater improvement in device temperature over a conventional DBC and over insulated metal substrate (IMS) for 2000 mm² substrate area. For a smaller substrate area, e.g., 1200 mm², the multilayer substrate may provide a 20% or greater improvement over the IMS and around 10% or greater improvement compared to conventional DBC. Furthermore, the multilayer substrate may offer better performance than a high-performance DBC based double-sided cooling system with the additional benefit of low cost and low complexity. For the above reasons, the described multilayer substrate (e.g., DBCwCu) can be a viable alternative to the conventional double-sided cooling structure.

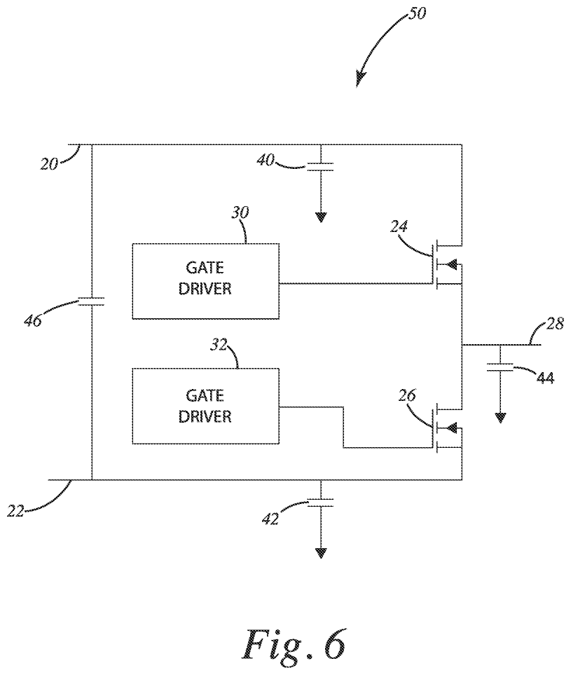

A power module provided in accordance with one embodiment for switching circuitry 50 is shown in FIGS. 2 and 6 and generally designated 200. Connections and components of the switching circuitry 50 in one embodiment are shown in further detail in FIG. 6, and include at least one switch, such as a WBG device.

The power module 200 may include a multilayer substrate 100, which may vary from application to application, configured to enhance heat transfer from the semiconductor devices to a heat sink 118. The multilayer substrate 100 may be a DBC based substrate to improve heat transfer from semiconductor devices to the heatsink for next-generation power electronic applications. The switching circuitry 50 of the power module 200 may be configured as a power converter device.

In the illustrated embodiment, the switching circuitry 50 includes a first switch 24 and a second switch 26 arranged in a half-bridge configuration with first and second gate drivers 30, 32 coupled respectively to the first and second switches 24, 26. In the half-bridge configuration, the first switch 24 is the top, upper, or high-side switch, and the second switch 26 is the bottom, lower, or low-side switch. Although the first switch 24 is shown as a single switch, it is to be understood that multiple switches may be provided in the circuitry to provide the functionality of the first switch 24, such as multiple switches provided in parallel with each other to provide high current depending on application needs in a half-bridge configuration. The functionality of the second switch 26 also may be achieved via more than one switch, such as multiple switches in parallel. A multiple switch configuration based on the switching circuitry 50 can be provided in the power module 200. Additional example switching configurations are described in U.S. Pub. 2021/0210477, entitled POWER MODULE WITH ORGANIC LAYERS, filed Oct. 30, 2020 to Gurpinar et al. —the disclosure of which is hereby incorporated by reference in its entirety.

The first and second gate drivers 30, 32 may include circuitry for controlling the first and second switches 24, 26 and may provide external connections to enable external circuitry (not shown) to control operation of the first and second switches 24, 26. In one embodiment, the circuitry of the first and second gate drivers 30, 32 may be conductors that provide an electrical path between external circuitry and respective gates of the first and second switches 24, 26. The switching circuitry 50 in the illustrated embodiment is configured to receive power from a DC power bus via a DC positive terminal 20 and a DC negative terminal 22. Power provided to the switching circuitry 50 may vary depending on the application and is not limited to DC power.

The switching circuitry 50 may include capacitance that is inherent to the circuit or provided via a discrete capacitor, or a combination thereof. In the illustrated embodiment, the switching circuitry 50 includes a DC link capacitor 46 and parasitic capacitance 40, 42.

The switching circuitry 50 in the illustrated embodiment includes an output terminal 28 connected to the outputs of the first and second switches 24, 26. The output terminal 28, by virtue of the connection to the first and second switches 24, 26, may be coupled to the common mode capacitance 44 associated with the first and second switches 24, 26. The common mode capacitance 44 may correspond to the intrinsic capacitance formed by the substrate in conjunction with the switching circuitry 50.

The first and second switches 24, 26 in one embodiment may form a half-bridge configuration with SiC MOSFETs (e.g., 10 mΩ, 900V) or GaN-based switches, and the switching circuitry 50 may include associated gate driver circuitry 30, 32, a DC link capacitor 46 and power terminals 20, 22.

The power module 200 in the illustrated embodiment packages the switching circuitry 50 in a manner that enhances heat dissipation from the switching circuitry 50 to a heat sink 118.

The power module 200 in the illustrated embodiment includes a multilayer substrate-based layout with first and second switches 24, 26 in the form of WBG devices in order to form a WBG power device-based power module. As described herein, in one embodiment, the power module 200 includes direct bonded copper (DBC) and copper tiles for a WBG power device-based power module.

In the illustrated embodiment, the power module 200 is configured with a multilayer substrate 100. The multilayer substrate 100 may include a dielectric layer 114, a second copper layer 112, and a first copper layer 116. The first and second copper layers 116, 112 may be disposed on opposing sides of the dielectric layer 114. The dielectric 114 in one embodiment may be ceramic, such as ceramic Al₂O₃, AlN, or silicon nitride Si₃N₄, with high thermal conductivity (e.g., about 150 W/mK or greater). The first and second copper layers 116, 112 may be approximately 0.3 mm thick—but the present disclosure is not so limited and the layers may be any thickness.

The second copper layer 112 in one embodiment may be thermally coupled to a heat sink 118 via a thermal interface 110. The thermal interface 110 may vary from application to application. In one embodiment, the thermal interface 110 may be approximately 0.25 millimeters thick, with a thermal conductivity of 10 W/m K or greater.

The heat sink 118 may also vary depending on the application. In one embodiment, the heat sink 118 may be formed of aluminum or copper and operable to dissipate heat generated by the switching circuitry 50 of the power module 200 and dissipated through the multilayer substrate 100.

In a DBC-based substrate, heat from the semiconductor 210A device may not be able to spread efficiently due to the thinness of the first copper layer 116 and highly conductive dielectric layer 114 (e.g., dielectric insulator). Heat generally comes down vertically with a 45° angle from the semiconductor device 210A. Thus, a small area of the multilayer substrate 100 may actively take part in heat transfer. By adding a thick, highly conductive material (e.g., a copper tile) underneath the semiconductor chip 210A, heat spreading may be improved heat transfer performance, as shown in FIG. 2.

For instance, the multilayer substrate 100 in the illustrated embodiment includes at least one a copper tile disposed between an integrated circuit chip (e.g., a switch similar to one of the switches 24, 26 described herein). A first copper tile 120A may be disposed between an IC chip 210A and the first copper layer 116. Optionally, a second copper tile 120B may be disposed between an IC chip 210B and the first copper layer 116. The first copper tile 120A and the second copper tile 120B may be configured similarly. The copper tile 120A may be provided between the semiconductor chip 210A and the first copper layer 116, where the first copper tile 120A is substantially thicker than the first copper layer 116.

The first copper tile 120A may include a first side and a second side that opposes the first side, with the first side of the first copper tile 120A being thermally coupled to the IC chip 210A. The second side of the first copper tile 120A may be thermally coupled to the first copper layer 116. Thermal Coupling to the IC chip 210A may be provided via a thermally conducting layer 124A provided between the first side of the first copper tile 120A and the IC chip 210A. Thermal coupling to the first copper layer 116 may be provided via a thermally conducting layer 122A provided between the second side of the first copper tile 120A and the first copper layer 116. The thermally conducting layers 122A, 124A may be solder—although the present disclosure is not so limited.

As described herein, the second copper tile 120B may be similar to the first copper tile 120A. For instance, the second copper tile 120B may include first and second sides, with a first side thermally coupled to an IC chip 210B via a thermally conducting layer 124B. Additionally, the second copper tile 120B may be thermally coupled to the first copper layer 116 via a thermally conducting layer 122B.

The first copper tile 120A and/or the second copper tile 120B may have a predetermined thickness that is significantly greater than the thickness of the first copper layer 116. For instance, the first copper tile 120A may have a thickness in the range of 0.5 mm to 2.5 mm, optionally about 1.5 mm, and the first copper layer 116 may have a thickness of about 0.3 mm. The second copper tile 120B may have a similar thickness configuration. In describing the first copper tile 120A and/or the second copper tile 120B as copper, it is to be understood that the first copper tile 120A and/or the second copper tile 120B are a copper-based material, including substantially pure copper or a copper-based alloy.

The first copper tile 120A may take any shape and is not limited to the shape depicted in the illustrated embodiment. For instance, polygon (e.g., rectangular or hexagonal) shapes or bar shapes may be utilized. The first copper tile 120A in one embodiment may correspond to a dedicated conductive coupling between the first copper layer 116 and the IC 210A that is significantly thicker than the first copper layer 116 and operable to conduct heat in a spread manner from the IC 210A to the first copper layer 116. The overall area of the first side of the first copper tile 120A a maybe larger than the overall area of the IC 210A. For instance, the overall area of the first side of the copper tile 120A may be 50% larger than the overall area of the IC 210A. The larger area of the first side of the copper tile 120A may facilitate heat transfer from the IC 210A to the first copper layer 116 in a spread manner. For instance, the first copper tile 120A may be a 10×10×1.5 mm copper tile between the IC chip 210A and first copper layer 116 of the DBC substrate to improve heat transfer from the semiconductor device to a cold plate (e.g., the heat sink 118), which can optionally be coupled to a coolant system.

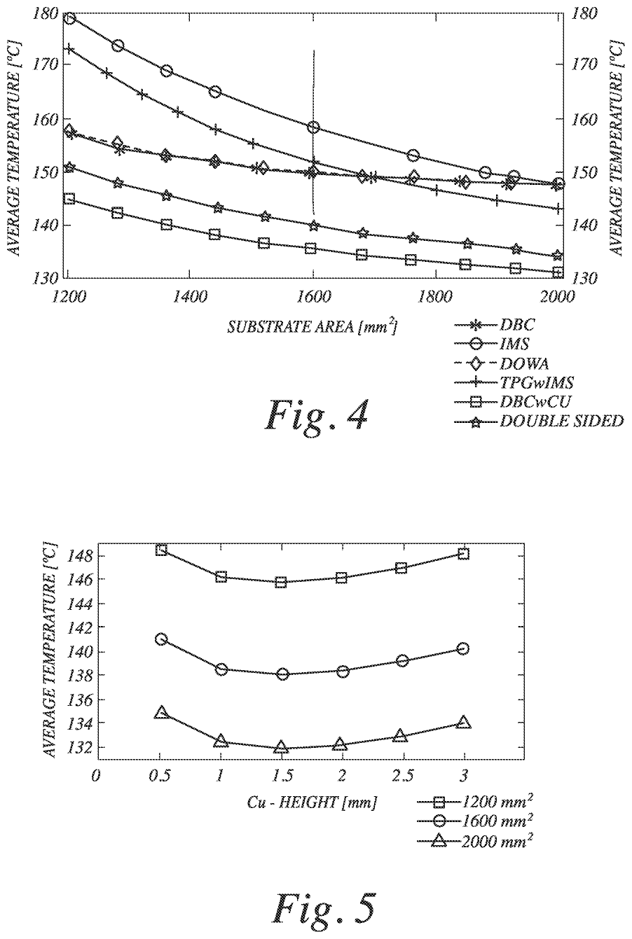

The multilayer substrate 100 according to one embodiment (e.g., a DBCwCu substrate) is compared against conventional substrate technologies in terms of heat transfer capabilities in FIG. 4. The comparison indicates that the disclosed multilayer substrate 100 provides much better heat extraction capability than the conventional DBC and offers much better performance than the high-performance double-side cooled DCB substrate. The conventional substrates include DBC, IMS, double sided, DOWA, which produces direct bonded aluminum and has no thermal interface between heatsink and DBA substrate, and IMSwTPG, which is thermally pyrolytic graphene (TPG) with insulated metal substrate (IMS).

As described herein, the thickness and overall shape of the first and second copper tiles 120A, 120B may vary from application to application. Performance for various copper thicknesses for a square shaped copper tiles are depicted in FIG. 5. It can be seen that at thickness of 1.5 mm for such a square shaped copper tile provide optimal heat dissipation—relative to a range in thicknesses between 0.5 mm and 3 mm. The 1.5 mm thick copper can keep the semiconductor device temperature to a minimum value. In this manner, increasing or decreasing the copper core thickness (e.g., the thickness of the copper tile) can adversely affect the device temperature.

The multilayer substrate 100 according to one embodiment of the present disclosure may provide a lower cost construction relative to a conventional double-sided DBC package or substrate, higher heat conductivity than the conventional DBC and double-sided packages or substrates, or higher volumetric density, or a combination thereof.

In one embodiment, the first and second copper tiles 120A, 120B are on top of a DBC substrate to increase the active heat transfer area. Although the multilayer substrate 100 includes an additional solder layer, it is noted that the additional solder layer or layers are optional and that the multilayer substrate 100 may provide better heat transfer performance than all other conventional substrates and can be a viable solution for next-generation power electronic applications.

In one embodiment, the power module 200 is configured such it that can be integrated into a high power density power electronic converter (e.g., an automotive traction drive system). The power module 200 in accordance with one embodiment of the present disclosure may be used in a variety of applications, including but not limited to automotive traction systems, solar inverters, and high performance-high power density power electronic converters.

In one embodiment, the power module 200 may be provided for use in a power converter. The power module 200 may be responsible for processing and transferring electrical power between a source and a load coupled electrically to the output terminal 28 with a target level of performance. The thermal efficiency of the power module 200 may be considered high due at least in part to the configuration of the multilayer substrate 100.

With the advancements in WBG based power semiconductor devices as the first and second switches 24, 26, such as SiC MOSFET and GaN HEMT, efficiency figures for the switching circuitry 50 on the power module 200 may be above 98%. However, even with high efficiency figures, a significant amount of heat can be generated in a relatively small area due to increased power demand from the electrical load on the output terminal 28, increased power density of the power module 200, and reduced chip size of the first and second switches 24, 26, such as with the introduction of a WBG device as the first and second switches 24, 26. The performance of the materials used for packaging of the power module 200, integration and design of thermal management of the power module 200 in accordance with one embodiment may enable effective operation in a variety of domains, such as electric vehicles.

For instance, with a WBG device used for the first and second switches 24, 26, the power module 200 may be configured to operate at much higher switching speed and the impact of parasitic components (e.g., parasitic inductance) introduced by the module design may be reduced for optimizing system efficiency and enhancing benefits of the high-speed switching devices.

Directional terms, such as “vertical,” “horizontal,” “top,” “bottom,” “upper,” “lower,” “inner,” “inwardly,” “outer” and “outwardly,” are used to assist in describing the invention based on the orientation of the embodiments shown in the illustrations. The use of directional terms should not be interpreted to limit the invention to any specific orientation(s).

The above description is that of current embodiments of the invention. Various alterations and changes can be made without departing from the spirit and broader aspects of the invention as defined in the appended claims, which are to be interpreted in accordance with the principles of patent law including the doctrine of equivalents. This disclosure is presented for illustrative purposes and should not be interpreted as an exhaustive description of all embodiments of the invention or to limit the scope of the claims to the specific elements illustrated or described in connection with these embodiments. For example, and without limitation, any individual element(s) of the described invention may be replaced by alternative elements that provide substantially similar functionality or otherwise provide adequate operation. This includes, for example, presently known alternative elements, such as those that might be currently known to one skilled in the art, and alternative elements that may be developed in the future, such as those that one skilled in the art might, upon development, recognize as an alternative. Further, the disclosed embodiments include a plurality of features that are described in concert and that might cooperatively provide a collection of benefits. The present invention is not limited to only those embodiments that include all of these features or that provide all of the stated benefits, except to the extent otherwise expressly set forth in the issued claims. Any reference to claim elements in the singular, for example, using the articles “a,” “an,” “the” or “said,” is not to be construed as limiting the element to the singular.

The embodiments of the invention in which an exclusive property or privilege is claimed are defined as follows:

1. A package comprising:
a substrate comprising a ceramic layer, a first Cu layer disposed on one side of the ceramic layer, and a second Cu layer disposed on an opposing side of the ceramic layer, wherein the second Cu layer is to be thermally coupled to a heat sink;
a Cu tile having a predetermined thickness, a first side, and a second side opposing the first side, wherein the first side of the Cu tile is to be thermally coupled to an integrated circuit (IC) chip; and
a thermally conducting layer sandwiched between the first Cu layer of the substrate and the second side of the Cu tile.

2. The package of claim 1, wherein the thermally conducting layer includes solder.

3. The package of claim 1, wherein the predetermined thickness of the Cu tile is in a range of 0.5 to 2.5 mm.

4. The package of claim 3, wherein the predetermined thickness of the Cu tile is about 1.5 mm.

5. The package of claim 3, wherein each of the first and second Cu layers of the substrate has a thickness of about 0.3 mm.

6. The package of claim 1, wherein the ceramic layer of the substrate includes one of Al₂O₃, AlN, or silicon nitride Si₃N₄.

7. A power module comprising
the package of claim 1;
an IC chip;
a second thermally conducting layer sandwiched between the first side of the Cu tile and the IC chip; and
the heat sink having a thermal interface with the second Cu layer of the substrate.

8. The power module of claim 7, wherein the second thermally conducting layer includes solder.

9. The power module of claim 7 configured as a power-converter device, wherein the IC chip includes GaN or SiC-based power-electronic switches.

10. A multilayer substrate for an integrated circuit (IC) component, the multilayer substrate comprising:
a dielectric layer;
first and second copper layers disposed on opposing sides of the dielectric layer; and
a copper tile including a first side and a second side that opposes the first side, the second side of the copper tile being coupled to the first copper layer, the first side of the copper tile configured to thermally couple to the IC component.

11. The multilayer substrate of claim 10 comprising a thermally conducting layer sandwiched between the first copper layer and the second side of the copper tile.

12. The multilayer substrate of claim 11 wherein the thermally conducting layer includes solder.

13. The multilayer substrate of claim 10 wherein the dielectric layer is a ceramic layer.

14. The multilayer substrate of claim 13 wherein the ceramic layer includes one of Al₂O₃, AlN, or silicon nitride Si₃N₄.

15. The multilayer substrate of claim 10 wherein the copper tile has a predetermined thickness.

16. The multilayer substrate of claim 10 wherein the second copper layer is operable to be thermally coupled to a heat sink.

17. A power module comprising:
the multilayer substrate of claim 10;
the integrated circuit component;
a second thermally conducting layer disposed between the first side of the copper tile and the integrated circuit component; and
a heat sink operable to thermally interface with the second copper layer.

18. The power module of claim 17 wherein the second thermally conducting layer includes solder.

19. The power module of claim 17 wherein the integrated circuit component includes a GaN-based or SiC-based power electronic switch.

20. The power module of claim 10 wherein the copper tile includes copper and one or more additional conductive metals.
